(19) United States
(12) Patent Application Publication
(10) Pub. No.: US 2010/0072518 A1
(43) Pub. Date: Mar. 25, 2010

(54) SEMICONDUCTOR DEVICES AND METHODS OF FABRICATING SAME

(75) Inventors: Shyh-Chiang Shen, Marietta, GA (US); Russell Dean Dupuis, Atlanta, GA (US); Yun Zhang, Atlanta, GA (US)

Correspondence Address: TROUTMAN SANDERS LLP;5200 BANK OF AMERICA PLAZA, 600 PEACHTREE STREET, N.E., SUITE 5200, ATLANTA, GA, 30308-2216, US

(73) Assignee: Georgia Tech Research Corporation, Atlanta, GA (US)

(21) Appl. No.: 12/559,444

(22) Filed: Sep. 14, 2009

Related U.S. Application Data
(60) Provisional application No. 61/096,428, filed on Sep. 12, 2008.

(51) Int. Cl. H01L 29/737; H01L 21/306; H01L 31/107

(52) U.S. Cl. 257/197; 438/745; 257/438; 257/E21.22; 257/E31.063; 257/E29.188; 257/76

(57) ABSTRACT

Methods of fabricating semiconductor devices using electrode-less wet-etching techniques to reduce defect densities on etched group III-nitride semiconductor surfaces are described herein. The methods generally involve contacting an etched surface of a component of a semiconductor device with a solution comprising a metal hydroxide and an oxidizing agent effective to reduce a roughness of the etched surface, wherein the etched surface is formed from a composition comprising a nitride of a group III element. Improved semiconductor devices are also disclosed.

### CROSS-REFERENCE TO RELATED APPLICATION

The present application claims the benefit of U.S. Provisional Patent Application Ser. No. 61/096,428, filed 12 Sep. 2008, and entitled “Method of Manufacture of III-N Semiconductor Devices Using Electrode-Less Photon-Assisted Wet Etching Techniques,” which is hereby incorporated by reference in its entirety as if fully set forth below.

### STATEMENT OF FEDERALLY SPONSORED RESEARCH

The United States Government might have certain rights in this invention pursuant to Grant No. FA8718-07-C-0002 awarded by the United States Air Force.

### TECHNICAL FIELD

The various embodiments of the present invention relate generally to methods of making semiconductor devices. More particularly, the various embodiments of the present invention relate to methods of treating the various surfaces of semiconductor device components and to the surface-treated semiconductor devices formed therefrom.

### BACKGROUND

Semiconductor compositions formed from nitrides of Group III elements (e.g., Al, Ga, and In) and their alloys have great potential for application in high-power or high-frequency optoelectronic devices. For example, Gallium nitride is used in many applications such as lasers and light-emitting diodes (LEDs) in the visible and ultraviolet emission range, as well as for high-power field-effect transistors. LEDs generally require a device area defined by deep mesa etching. Similarly, high-performance metal—semiconductor field-effect transistors (MESFETs) and high electron mobility transistors (HEMTs) generally require a recessed short gate. The mesa isolation and fabrication of recessed gate structures requires the use of a well-controlled etching technique that results in a low level of damage on the etched surface and sidewalls.

Etching technologies for group III nitrides (III-N) fall into two general categories: dry etching and wet etching. Since GaN and other III-N are chemically stable and inert materials, processing of III-N is currently most commonly performed using dry plasma etching. Plasma-based dry etching methods, such as inductively coupled plasma (ICP) etching or reactive ion etching (RIE), often induce ion damage to the device surface as well as to mesa sidewalls. Consequently, these methods can decrease the device performance by enabling an increase in surface leakage. Wet etching techniques, on the other hand, provide an alternative to dry etching in order to reduce plasma-induced surface damage. Conventional chemical wet etching, however, is not as effective on high-quality III-N materials. To overcome this, photoelectrochemical (PEC) etching and/or ultraviolet-assisted wet etching have been proposed as replacements to plasma dry etching.

Wet etching in III-N materials still suffers from problems. First, UV-assisted wet etching is selective to n-type III-N materials. The etching rate on p-type III-N materials is not readily ascertainably, so this technique cannot be used to fabricate mesas on p-type materials. In addition, typical UV-assisted wet etching tends to have higher etching rates on sites where the defect density is high.

There accordingly remains a need in the art for an improved etching technique that can be used to achieve highly uniform etched surfaces. It is to the provision of such techniques and the semiconductor devices produced therefrom that the various embodiments of the present invention are directed.

### BRIEF SUMMARY

Briefly described, the various embodiments of the present invention provide semiconductor devices and methods of making the semiconductor devices. For example, various embodiments of the present invention are directed to methods of treating surfaces of III-N semiconductor devices. The methods generally include contacting an etched surface of a component of a semiconductor device with a solution comprising a metal hydroxide and an oxidizing agent. The etched surface is formed from a composition comprising a nitride of a group III element (III-N). The method also includes reducing a roughness of the etched surface. In some cases, the roughness of the etched surface can be reduced at least about 20%. In other cases, the roughness of the etched surface can be reduced at least about 75%.

The metal hydroxide can be potassium hydroxide (KOH). The potassium hydroxide can have a concentration less than or equal to about 0.01 M.

The oxidizing agent can be potassium persulfate or potassium peroxydisulfate (K₂S₂O₈). The potassium persulfate can have a concentration less than or equal to about 0.01 M.

The method can also include illuminating the etched surface with a light source configured to produce ultraviolet light. Such ultraviolet light can have a wavelength of about 180 nanometers to about 380 nanometers. Further, such ultraviolet light can have a power less than or equal to about 0.5 Watts per square centimeter.

In some cases, the temperature of the contacting step can be less than or equal to about 100 degrees Celsius. Similarly, the duration of the contacting can be less than or equal to one hour in certain situations.

After the reducing step, the surface treated semiconducting device can have a leakage current that is reduced at least one order of magnitude.

Reducing the roughness of the etched surface can involve removing damage to the etched surface caused by an etching step prior to the contacting.

Another method of treating a surface of a semiconductor device includes etching a surface of a component of a semiconductor device, wherein the surface is formed from a composition comprising a nitride of a group III element, followed by contacting an etched surface of the component of the semiconductor device with a solution comprising potassium hydroxide at a concentration less than or equal to about 0.01 M and potassium persulfate at a concentration less than or equal to about 0.01 M. The contacting involves a temperature less than or equal to about 100 degrees Celsius and a duration less than or equal to about one hour. The method further involves reducing a roughness of the etched surface. In some cases, the roughness of the etched surface can be reduced at least about 20%. In other cases, the roughness of the etched surface can be reduced at least about 75%.

This method can also include illuminating the etched surface with a light source configured to produce ultraviolet light having a wavelength of about 180 nanometers to about 380 nanometers and a power output of less than or equal to about 0.5 Watts per square centimeter.

After the reducing, this method produces a semiconducting device that has a leakage current which is reduced at least one order of magnitude.

Reducing the roughness of the etched surface can involve removing damage to the etched surface caused by the etching step.

Other embodiments of the present invention are directed to avalanche photodiode devices. Such an avalanche photodiode device generally includes a p-type layer of a nitride of a group III element, an n-type layer of the nitride of the group III element, and an intrinsic or unintentionally doped layer of the nitride of the group III element. The intrinsic layer is disposed between the p-type and n-type layers. The avalanche photodiode device exhibits a photocurrent gain greater than or equal to about 10⁴ and a dark current less than or equal to about 10⁻⁷ Amps per square centimeter at a bias value less than or equal to about 50% of an avalanche breakdown voltage for the avalanche photodiode device.

In some situations, the nitride of the group III element is gallium nitride.

The avalanche photodiode can further include an etched mesa structure having an etched surface, wherein the etched surface was contacted with a solution comprising potassium hydroxide at a concentration less than or equal to about 0.01 M and potassium persulfate at a concentration less than or equal to about 0.01 M. In some cases, the avalanche photodiode device has a leakage current that is reduced at least one order of magnitude than if the etched surface was not contacted with the solution.

The avalanche photodiode can be sensitive to ultraviolet radiation having a wavelength of about 280 nanometers to about 360 nanometers.

Other embodiments of the present invention are directed to double-heterojunction bipolar transistor (DHBT) devices. Such a DHBT device generally includes a first layer comprising a first composition comprising a nitride of a group III element, wherein the first layer is p-type or n-type, and two additional layers, each comprising a second composition comprising a nitride of a group III element, wherein the two additional layers have an opposite polarity from the first layer, and wherein the first layer is disposed between the two additional layers. The DHBT further includes an etched mesa structure having an etched surface, wherein the etched surface was contacted with a solution comprising potassium hydroxide at a concentration less than or equal to about 0.01 M and potassium persulfate at a concentration less than or equal to about 0.01 M. The first and second III-N compositions may or may not be the same. The DHBT exhibits a common emitter current gain greater than 1. In certain cases, the common emitter current gain is greater than 40.

In some situations, the DHBT can be fabricated from a p-type InGaN layer interposed between two n-type GaN layers.

In some cases, the DHBT device has a leakage current that is reduced at least one order of magnitude than if the etched surface was not contacted with the solution.

Other aspects and features of embodiments of the present invention will become apparent to those of ordinary skill in the art, upon reviewing the following detailed description in conjunction with the accompanying figures.

### BRIEF DESCRIPTION OF THE DRAWINGS

FIG. 1 graphically depicts (a) the effects of KOH concentration, K₂S₂O₈ concentration, and UV power on the surface roughness improvement, and (b) the interaction effects of KOH, K₂S₂O₈, and power on surface roughness improvement in accordance with EXAMPLE 1.

FIG. 2 includes two-dimensional (2D) atomic force microscope (AFM) plots showing the ICP-etched n-type GaN surface (a) before the surface treatment and (b) after the surface treatment in accordance with EXAMPLE 1.

FIG. 3 includes three-dimensional (3D) AFM images of an etched mesa sidewall (a) before wet etching and (b) after wet etching, obtained with a rotation angle of 85 degrees and a pitch angle of 10 degrees, in accordance with EXAMPLE 1.

FIG. 4 graphically illustrates a comparison of the reverse leakage current for GaN p-i-n (PIN) diodes grown on SiC substrates with different post-etching treatment techniques in accordance with EXAMPLE 1.

FIG. 5 is a scanning electron microscope (SEM) image of a fabricated GaN avalanche photodiode (APD) with an optical window 50 micrometers (μm) in diameter in accordance with EXAMPLE 2.

FIG. 6 illustrates representative reverse-biased current-voltage (I-V) characteristics of fabricated GaN APDs with and without UV light illumination in accordance with EXAMPLE 2.

FIG. 7 graphically depicts the room-temperature voltage-dependent spectral response of a fabricated 60-μm-diameter GaN PIN APD, in accordance with EXAMPLE 2, with the originally overlapped curves split in the plot for clear presentation.

FIG. 8 is a schematic illustration of the possible mechanisms that are responsible for the band-edge absorption spectrum red-shift, with the nonzero probability density in the forbidden energy gap resulting in the Franz-Keldysh red-shifting in the absorption spectrum of the APD according to EXAMPLE 2.

FIG. 9 provides a secondary ion mass spectrometry (SIMS) profile of a heterostructure field effect transistor (HFET) grown on a semi-insulating (SI) GaN substrate without surface treatment in accordance with EXAMPLE 3.

FIG. 10 graphically illustrates the charge concentrations as a function of depth for a HFET grown using a Cp₂Fe dopant precursor pre-purge on a SI—GaN substrate in accordance with EXAMPLE 3.

FIG. 11 graphically illustrates the charge concentrations as a function of depth for a HFET grown on a SI—GaN substrate with PEC etching prior to the epitaxial growth in accordance with EXAMPLE 3.

FIG. 12 graphically illustrates the measured common-emitter characteristics of a GaN/InGaN double heterojunction bipolar transistor (DHBT) with an emitter area (A_{E}) of about 20×about 20 μm² in accordance with EXAMPLE 4.

FIG. 13 graphically illustrates a Gummel plot of a GaN/InGaN DHBT with an A_{E} of about 20×about 20 μm² in accordance with EXAMPLE 4.

FIG. 14 graphically illustrates current collector density (JO over common-emitter D.C. current gain (β) relative to emitter periphery (L_{E}) over emitter area (A_{E}) for various current collector densities, wherein the voltage between the collector and the base (V_{CB}) was fixed at 10 Volts and the linearly fitted slopes correspond to the surface leakage current density (K_{B,surf}), in accordance with EXAMPLE 4.

### DETAILED DESCRIPTION

Referring now to the figures, wherein like reference numerals represent like parts throughout the several views, exemplary embodiments of the present invention will be described in detail. Throughout this description, various components can be identified as having specific values or parameters, however, these items are provided as exemplary embodiments. Indeed, the exemplary embodiments do not limit the various aspects and concepts of the present invention as many comparable parameters, sizes, ranges, and/or values can be implemented. The terms “first,” “second,” and the like, “primary,” “secondary,” and the like, do not denote any order, quantity, or importance, but rather are used to distinguish one element from another. Further, the terms “a”, “an”, and “the” do not denote a limitation of quantity, but rather denote the presence of “at least one” of the referenced item.

The various embodiments of the present invention provide improved methods for fabricating semiconductor devices, and the improved semiconductor devices themselves. More specifically, the improved methods and devices make use of electrode-less wet-etching techniques to reduce defect densities and/or surface roughness on already-etched semiconductor device surfaces. In general, the methods can be applied to improve the surface quality of any surface of the semiconductor device, including those of the substrate or any other component. Advantageously, because the improved methods and devices use electrode-less techniques, the substrates on which the semiconductor devices are fabricated can be conducting substrates (e.g. n-GaN, n-SiC, and the like) or insulating substrates (e.g., sapphire, Si, SiO₂, and the like). In addition, it is also possible to apply the improved methods directly to an already-fabricated semiconductor device, rather than to individual layers or components of the device during growth. As a result of these features and benefits, the improved methods and devices can provide a simple, low-cost way to achieve etching uniformity in semiconductor device fabrication.

The semiconductor surfaces to which the various embodiments of the present invention apply are those comprising nitrides of the group III elements (III-N). By way of example, III-N compositions can include AlN, GaN, InN, ternary alloys comprising III-N (e.g., AlGaN, InGaN, InAlN, GaNAs, and the like), and quaternary alloys comprising III-N (e.g., AlGaInN, AlGaNAs, GaInNP, GaNPAs, and the like) in varying atomic ratios. Further, the III-N compositions can be doped or undoped when processed using the methods of the present invention.

In general, the methods of the various embodiments of the present invention involve fabricating a III-N-containing semiconductor device structure. For example, this can include fabrication of lasers, light-emitting diodes (LEDs), high-performance metal—semiconductor field-effect transistors (MESFETs), high electron mobility transistors (HEMTs), heterostructure field effect transistors, and the like. These devices, and their associated methods of manufacture, are known to those skilled in the art to which this disclosure pertains.

Once the III-N-containing semiconductor device structure has been grown, it may require etching to create mesa structures and/or recessed gate structures. This etching step, which for illustrative convenience will be hereinafter termed the “primary etching” step, can be accomplished using any etching technique. By way of example, the primary etching step can be accomplished using dry etching or wet etching techniques. Suitable dry etching techniques include inductively coupled plasma (ICP) etching, reactive ion beam etching (RIE), chemically assisted ion-beam etching (CAIBE), and the like. Suitable wet etching techniques include photoelectrochemical (PEC) etching, ultraviolet-assisted wet etching, and the like. The use of these various dry and wet etching techniques are known to those skilled in the art to which this disclosure pertains.

Regardless of the primary etching step or technique employed, there is frequently etching-induced damage, in particular surface damage, that can induce additional current leakage paths, which can degrade the device performance significantly. To address this problem, the methods of the various embodiments of the present invention utilize a simple electrode-less wet etching technique to modify the already-etched surface of the semiconductor device for effective surface leakage reduction. For illustrative convenience, this step will be hereinafter termed the “surface treatment” step. To clarify, the surface treatment step can be applied in combination with any primary etching technique(s) to form a multi-step etching sequence so that, for example, one can take advantage of fast mesa etching with dry etching techniques, followed by a damage-removing surface treatment with the electrode-less wet chemical etching. As etching-induced damage is removed by the surface treatment step, the fabrication-related device degradation can be minimized, and high-performance III-N electronic and optoelectronic devices can be realized.

The surface treatment step generally includes contacting at least an etched surface of the component of a semiconductor device with a surface-treatment solution. It should be noted that, in some cases, the entire semiconductor device can be contacted with the surface-treatment solution. The surface-treatment solution includes a hydroxide and an oxidizing agent. The hydroxide and the oxidizing agent act in concert to reduce the roughness of the etched surface that has been contacted with the surface-treatment solution.

Hydroxides that can be used to form the surface-treatment solution of the surface treatment step include ammonium hydroxide, tetramethylammonium hydroxide, cesium hydroxide, sodium hydroxide, potassium hydroxide, and the like. In exemplary embodiments, the hydroxide is a metal hydroxide. The oxidizing agent that can be used to form the surface-treatment solution of the surface treatment step includes sodium persulfate (Na₂S₂O₈), potassium chromate (K₂Cr₂O₇), potassium permanganate (KMnO₄), potassium persulfate (K₂S₂O₈), and the like. In exemplary embodiments, the oxidizing agent is a metal persulfate. It should be noted that when a metal hydroxide and a metal persulfate are used to form the surface-treatment solution, the metal can be the same or different for the two components of the solution.

In some cases, the surface treatment step can be a photon-assisted step. That is, a light source can be implemented in order to facilitate or expedite the reduction in the roughness of the etched surface. In exemplary embodiments, any light source that is configured to produce ultraviolet (UV) light, which can be irradiated on the etched surface, can be used. Examples of such light sources include lasers, arc lamps, UV fluorescent lamps, gas discharge lamps, and the like. The UV light can have a wavelength of about 180 nanometers to about 380 nanometers. In some cases, broad-band UV light can be irradiated on the etched surface, while, in other cases, narrow-band (and even single wavelength) UV light can be irradiated on the etched surface. Exemplary single wavelengths that can be used include 325 nanometers and 365 nanometers.

In some cases, the roughness of the etched surface can be reduced at least about 20%. In other cases, the roughness of the etched surface can be reduced at least about 75%. Naturally, the reduced surface roughness provides the surface with greater surface uniformity, which can enable semiconductor devices with improved performance. For example, the reduced roughness can provide better crystallographic stoichiometry to the surface. In addition, the reduced roughness can be attributed to a removal of any or all of the etching damage caused by the primary etching step.

To avoid the possibility that the hydroxide and the oxidizing agent can remove much more than just surface damage from the primary etching step, the parameters of the surface treatment step, which can include concentrations of the hydroxide and oxidizing agent in the surface-treatment solution, the intensity of the optional UV irradiation, the temperature and duration of the surface treatment step, and the like, should be controlled. Controlling these parameters will be understood to those skilled in the art to which this disclosure pertains. For example, those skilled in the art to which this disclosure pertains would understand that lowering all of these parameters together can result in less effective surface treatment, while increasing all of these parameters together can result in more effective treatment.

By way of illustration as to guidelines for the parameters of the surface treatment step, reference will be made to a surface treatment solution comprising potassium hydroxide and potassium persulfate. In exemplary embodiments, the potassium hydroxide has a concentration less than or equal to about 0.01 moles per liter (M). Larger concentrations can result in increased etching and, potentially, adverse effects. In exemplary embodiments, the potassium persulfate has a concentration less than or equal to about 0.01 M. As with the potassium hydroxide, larger concentrations of the potassium persulfate can result in increased etching and, potentially, adverse effects. With respect to the optional use of UV irradiation, the UV light will have a power less than or equal to about 0.5 Watts per square centimeter (W/cm²) in exemplary embodiments. The surface treatment step in this illustrative example should be carried out at a temperature of less than or equal to about 100 degrees Celsius. Similarly, the surface treatment step in this illustrative example should be carried out for a duration of less than or equal to about one hour. In exemplary embodiments, the surface treatment step in this illustrative example is carried out at room temperature for a duration of less than five (5) minutes.

Use of the surface treatment step after the primary etching step can produce semiconductor devices with significantly improved properties. For example, devices with leakage currents (and leakage current densities) decreased by at least one order of magnitude (relative to devices fabricated using only the primary etching step) have been observed.

One example of an improved semiconductor device produced according to the methods described above is an avalanche PIN photodiode device. Such an avalanche photodiode (APD) device generally includes a p-type layer of a III-N composition, an n-type layer of a III-N composition, and an intrinsic or unintentionally doped layer of a III-N composition that is interposed between the p-type and n-type layers. Exposing an already-etched APD device to the surface treatment step above can result in significantly increased avalanche gains and significantly lower leakage current densities (relative to an avalanche photodiode fabricated using only a primary etching step). For example, GaN-based APDs that are processed using the methods described above can exhibit photocurrent gains greater than or equal to about 10⁴ and dark currents less than or equal to about 10⁻⁷ Amps per square centimeter (A/cm²) at bias values less than or equal to about 50% of the avalanche breakdown voltages for the devices. Furthermore, APDs processed using the methods described above can exhibit breakdown voltages that are increased by at least 5%.

One example of an improved semiconductor device produced according to the methods described above is a double-heterojunction bipolar transistor (DHBT). Such a DHBT device generally includes one of a p- or n-type layer of a III-N composition interposed between the other of a n- or p-type layer of a III-N composition. For example, the structure can have a p-type layer sandwiched between two n-type layers, or an n-type layer sandwiched between two p-type layers. With DHBTs, the III-N composition of each polarity layer does not have to be the same. For example a DHBT can be fabricated from a p-type InGaN layer interposed between two n-type GaN layers. Such devices, processed using the methods described above, can exhibit common emitter current gains greater than 1. In certain cases, common emitter current gains greater than 40 can be achieved.

### EXAMPLES

The present disclosure is further exemplified by the following non-limiting examples.

### Example 1

In this example, the surface treatment comprised UV-enhanced electrode-less wet-etching to reduce roughness and surface leakage paths in ICP-etched III-N devices. The surface treatment process made use of an aqueous solution with potassium hydroxide (KOH) as the etchant, catalyzed by UV light. Specifically, ICP dry etching was used for p- and n-layer mesa etching. The n-type surface was then exposed to a UV-assisted wet etching treatment to remove only a few mono-layers of III-N surface atoms and to improve leakage current characteristics. In contrast to conventional PEC etching, potassium persulphate (K₂S₂O₈) was used as an oxidant to eliminate the need for electrodes.

To study the effects of the various conditions of the surface treatment, a three-factor, two-tiered experimental design was used, and certain etching conditions were found to achieve a reduction of the leakage current in III-N p-n junctions by at least one order of magnitude. That is, experiments were conducted to determine the correlation between UV illumination power, KOH concentration, and the K₂S₂O₈ concentration on post-treatment surface morphology and high-field leakage current.

Before wet etching, eight GaN samples, cut from a 2-inch sapphire wafer, were mesa etched by BCl₃/Cl₂ in an ICP system. The etching depth was about 1000 Angstroms (Å) with an etching rate of about 1000 Å/min. These etched samples were then used for the study where the KOH concentration, K₂S₂O₈ concentration, and UV light power were the three experimental variables. Each parameter was varied between a high level (H) and low level (L). This provided a total of eight different etching conditions. Each sample was randomly assigned to one of the eight etching conditions. Each of the chemicals was freshly prepared in de-ionized (DI) water just before each wet etching step, which was performed at room temperature. The values for the H and L levels for each parameter is listed in Table 1.

TABLE 1
Summary of Values for Variable Parameters

| | |
|---|---|
| High Level | Low Level |

| | | | | |
|---|---|---|---|---|
| KOK concentration | 0.0005 | M | 0.00025 | M |
| K₂S₂O₈ concentration | 0.002 | M | 0.001 | M |
| UV Power | 900 | W | 600 | W |

The etching time was set to about 5 minutes for each etching condition. Due to the variation in the surface smoothness from the ICP etching, the percentage of surface roughness improvement before and after the surface treatment was used as the output response. Root mean square (RMS) surface roughness (in nm) was measured using an atomic force microscope (AFM) before and after ICP etching. The positions of the AFM scan were recorded so that the same locations could be analyzed to ensure a valid comparison. Each sample was surface-treated using one of the 8 etching conditions and a post-etching AFM scan was evaluated to determine the surface treatment's effectiveness. The surface morphology improvement was defined as: RMS improvement (ΔRMS in %)=[(RMS before wet etching)−(RMS after wet etching)]/(RMS before wet etching). The results are summarized in Table 2.

TABLE 2
Summary of Sample Response to Surface Treatment Conditions

| | | | | RMS (nm) | RMS (nm) | |
|---|---|---|---|---|---|---|
| Sample | UV | KOH | K₂S₂O₈ | before | after | Δ RMS (%) |
| 1 | H | L | L | 0.390 | 0.378 | 3.07 |
| 2 | H | H | L | 0.385 | 0.348 | 9.61 |
| 3 | H | L | H | 0.315 | 0.340 | −7.93 |
| 4 | H | H | H | 0.272 | 0.349 | −28.3 |
| 5 | L | L | L | 0.281 | 0.344 | −22.41 |
| 6 | L | H | L | 0.302 | 0.227 | 24.83 |
| 7 | L | L | H | 0.311 | 0.336 | −8.03 |
| 8 | L | H | H | 0.266 | 0.333 | −28.94 |

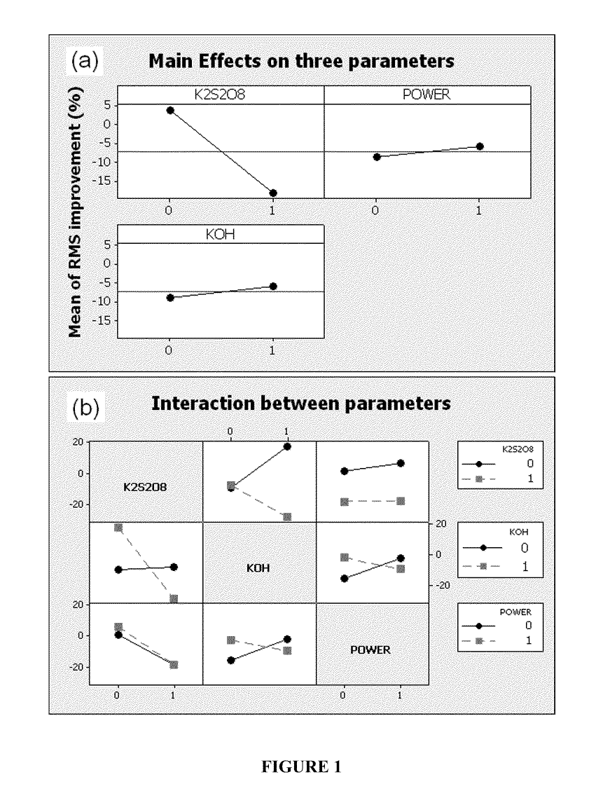

In Table 2, it is observed that certain etching conditions resulted in greater surface roughness (i.e., those indicated by a negative value in the ΔRMS), possibly due to aggressive etching and/or the presence of dislocation defects. With proper choices of etching conditions, however, smooth surfaces were achieved. To study the correlation between the variables, the main effect and their results were plotted in FIGS. 1 (a) and (b).

FIG. 1 (a) includes a set of plots showing the main effects of KOH concentration, K₂S₂O₈ concentration, and the UV illumination power on the surface roughness improvement. The data points were averaged for each parameter. The “L” level corresponds to “0” and the “H” level corresponds to a “1” in each plot. It was observed that the K₂S₂O₈ concentration had a significant effect: lowering the K₂S₂O₈ concentration improved the surface uniformity. FIG. 1 (b) includes a set of plots showing the interactions between [KOH], [K₂S₂O₈], and the UV illumination power. The variables in the diagonal boxes indicate the parameters used in the x-axis of each column. The interactions with the variable indicated in the row are shown with solid circles for the “H” levels and solid squares for the “L” levels, respectively. It can be seen that K₂S₂O₈ and KOH had significant interaction. The KOH concentration was also significant but its effect varied with different K₂S₂O₈ concentration. In etching conditions with low K₂S₂O₈ concentration, higher KOH concentration yielded smoother surfaces. On the other hand, if the K₂S₂O₈ concentration was high, higher KOH concentrations produced a rougher surface. One effective wet-etching-based surface treatment was achieved with a K₂S₂O₈ concentration in the vicinity of “L” level and a KOH concentration around the “H” level. The UV illumination power, however, may not be a dominant factor.

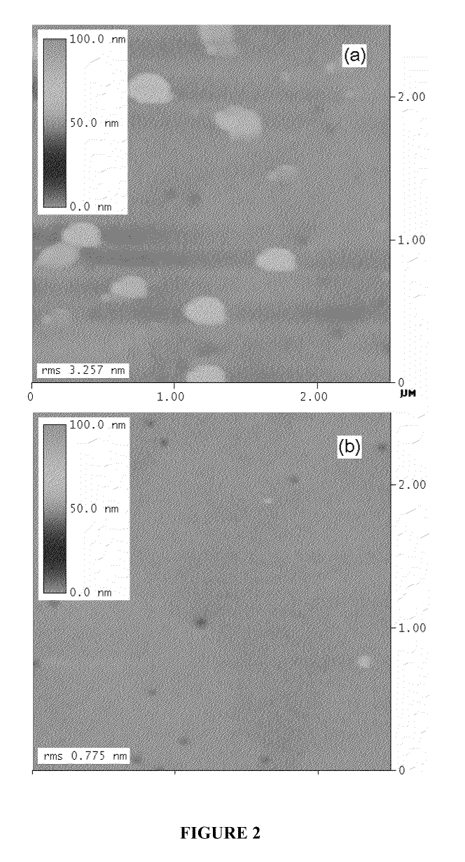

FIGS. 2 (a) and (b) include AFM images of an etched surface of n-type GaN taken before and after the surface treatment, respectively, using the conditions shown for Sample 6 in Table 1. For this sample, the surface roughness was improved by about 75% after the surface treatment when compared to the non-treated, ICP-etched surface (with an RMS value reduction from 3.527 nm to 0.775 nm). In FIG. 2 (a), there are some “spikes” induced by dry etching, but they were effectively removed by the surface treatment, as shown in FIG. 2 (b). This clearly indicates the ability of the surface treatment technique to effectively modify the surface morphology.

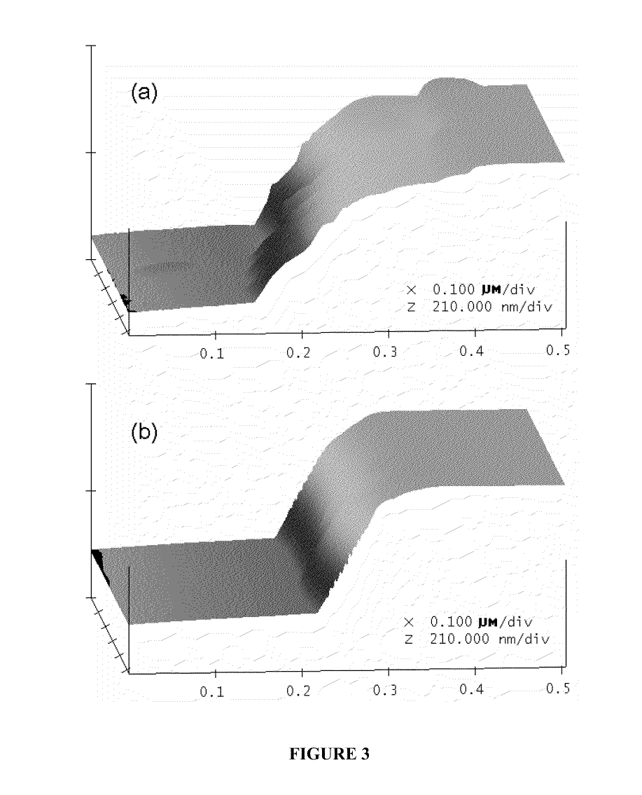

FIG. 3 provides 3D AFM images of the morphology of etched mesa sidewalls before and after the surface treatment. The surface treatment reduced the tapered mesa sidewall width from about 200 nm to less than about 100 nm. In addition, a much smoother sidewall was obtained.

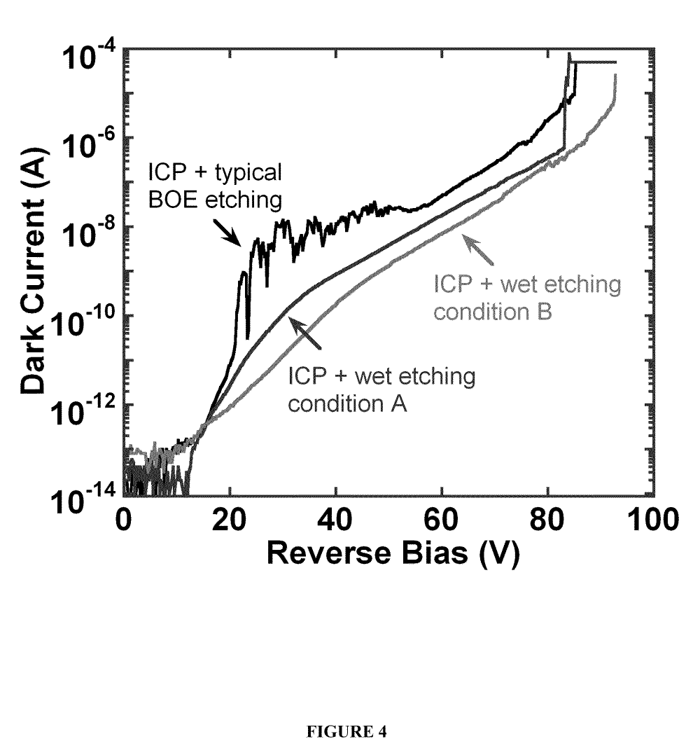

To study the efficacy of the side-wall leakage suppression, GaN PIN diodes grown on SiC substrates were fabricated with two of the surface treatment conditions. The first condition is mimics Sample 7 from Table 2 and the second condition mimics Sample 6 from Table 2. The results were compared with those devices fabricated without the surface treatment. Representative reverse-biased I-V curves with various etching conditions are shown in FIG. 4 (under the dark condition). It was found that, with a proper choice of surface treatment condition, the leakage current in PIN diodes can be reduced by at least one order of magnitude. The device breakdown voltage was extended to a higher voltage, and catastrophic breakdown was not observed with the surface-treated samples.

In summary, this example demonstrates a post-dry-etching surface treatment process for GaN minority carrier devices using a simple electrode-less UV-assisted wet etching technique. This study also provided certain conditions (e.g., a lower K₂S₂O₈ concentration level and a higher KOH concentration level) that can effectively reduce the leakage current as well as improve the surface morphology of the treated devices. Under these surface treatment conditions, device surface morphology and leakage current was improved and a much improved device leakage performance was achieved.

### Example 2

In this example, state-of-the-art GaN avalanche photodiodes (APDs) with typical avalanche photocurrent gains greater than about 10⁴ and dark currents less than about 10⁻⁷ Å/cm² for bias values up to 50% of the device avalanche breakdown voltage are demonstrated. The field-dependent absorption spectrum of the GaN-based p-i-n (PIN) diodes peaked around 360 nm with a short-wavelength cut-off shorter than 250 nm. The long-wavelength absorption spectrum, however, extended to the blue band (about 440 nm) due to electric-field-assisted tunneling absorption. The performance of these APD devices demonstrated the feasibility of employing III-N APDs for next-generation high-sensitivity deep ultraviolet (DUV) sensor array applications.

Experimentally, the GaN epitaxial materials in this example were grown by metal—organic chemical vapor deposition (MOCVD) using a reactor system equipped with a close-coupled showerhead growth chamber. The epitaxial layers were grown on an n-type free-standing “bulk” GaN substrate (supplied by Samsung Corning Inc.) with a nominal electron concentration of about 1×10¹⁸ cm⁻³. The APD comprised an about 2.5-μm-thick n-GaN:Si layer (η=5×10¹⁸ cm⁻³), followed by an about 0.28-μm-thick unintentionally doped (estimated η=5×10¹⁶ cm⁻³) GaN layer, and an about 0.1-μm-thick p-GaN:Mg layer atop to form a homojunction PIN diode. The approximated free-hole concentration was about 1×10¹⁸ cm⁻³ based on previous growth calibrations.

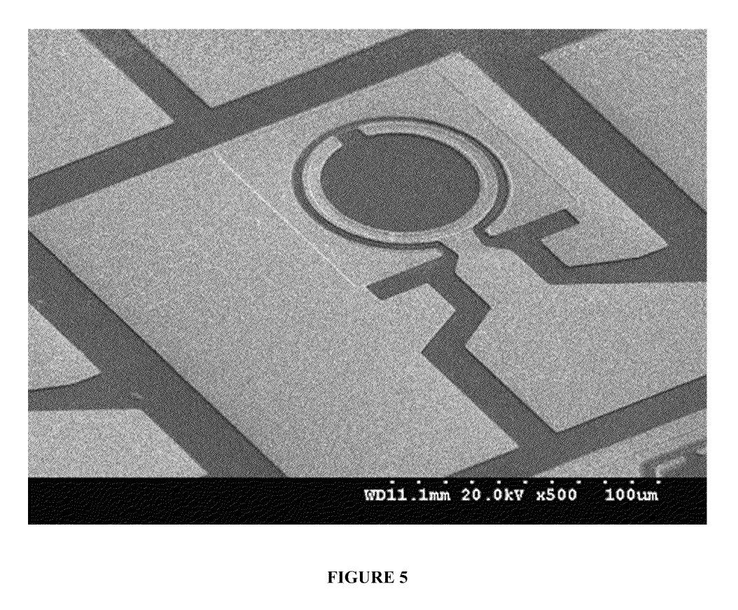

The APD device fabrication started with a low-damage chlorine-based inductively coupled plasma mesa etching. The p-type ohmic metals of Pd—Au were evaporated and annealed. The etched GaN surfaces were treated with the surface treatment of EXAMPLE 1. Then, n-type ohmic contact metals were deposited. A plasma-enhanced chemical vapor deposition silicon dioxide passivation layer was deposited and a Ti—Au layer was evaporated for interconnects and bonding pads. A scanning electron microscope (SEM) photograph of a fabricated GaN APD is shown in FIG. 5.

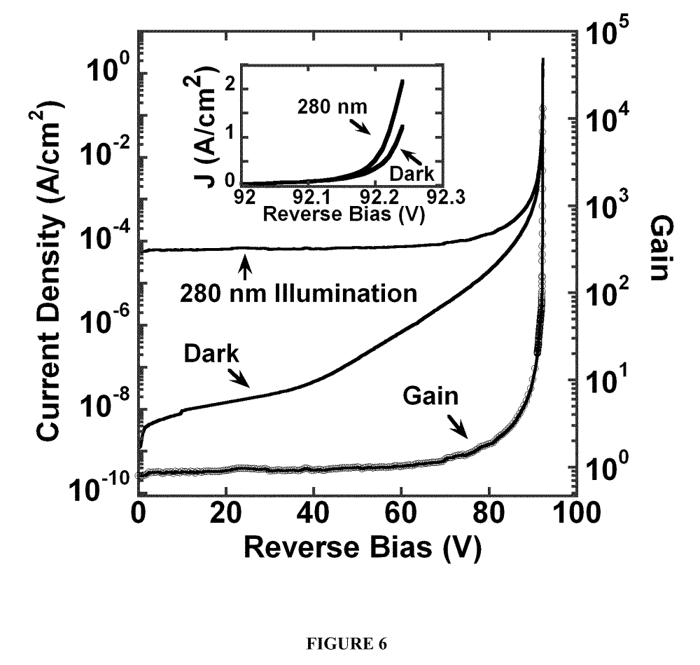

The fabricated devices were tested using a Keithley 4200 semiconductor characterization system, an integrated 150-W Oriel xenon (ozone-free) lamp, and ¼-m Cornerstone 260 monochromator/chopper system for both dc and spectral response measurements. Typical reverse-biased current-voltage (I-V) characteristics for both dark and illuminated conditions at about 280 nm are shown in FIG. 6. The devices under test had an etched mesa area of about 76 μm in diameter. Under dark conditions, the leakage current density was below about 10⁻⁷ A/cm² up to about 45 V. The breakdown voltage of the PIN diodes was around 92.3 V (or equivalently, about 2.6 MV/cm). The increase of the leakage current at higher reverse bias was attributed both to the bulk dislocation defects and surface states since the p-layer may be fully depleted beyond a reverse bias of 60 V. The thickness of the depleted p-layer region was calculated theoretically and was verified by capacitance—voltage measurements with an Agilent 4284A precision LCR meter up to about 40 V. With about 280-nm UV light illumination, the photocurrent remained approximately constant up to about 60 V before the impact ionization effect started to affect the current flow. The unity photocurrent I_{ph(unity)} and dark current I_{dark(unity)} were evaluated by taking the averaged photocurrent between 0 and about 60 V under illumination. The avalanche gain (G) was calculated by G=[Iₚₕ(V)−I_{dark}(V)]/[I_{ph(unity)}−I_{dark(unity)}] [12] and a gain of greater than about 14 000 was measured at about 92.25 V (see the inset of FIG. 6). Out of 40 APDs randomly measured across the about 8 mm×about 8 mm wafer piece, more than 20 of the devices exhibited a repeated avalanche gain of greater than about 1×10⁴ with a centralized distribution of avalanche gain between about 12 500 and about 15 000, with a low correlation between gain and mesa area (up to about 4536 μm²). This result indicated that the defect density may have been greatly suppressed through optimized material growth and device fabrication techniques.

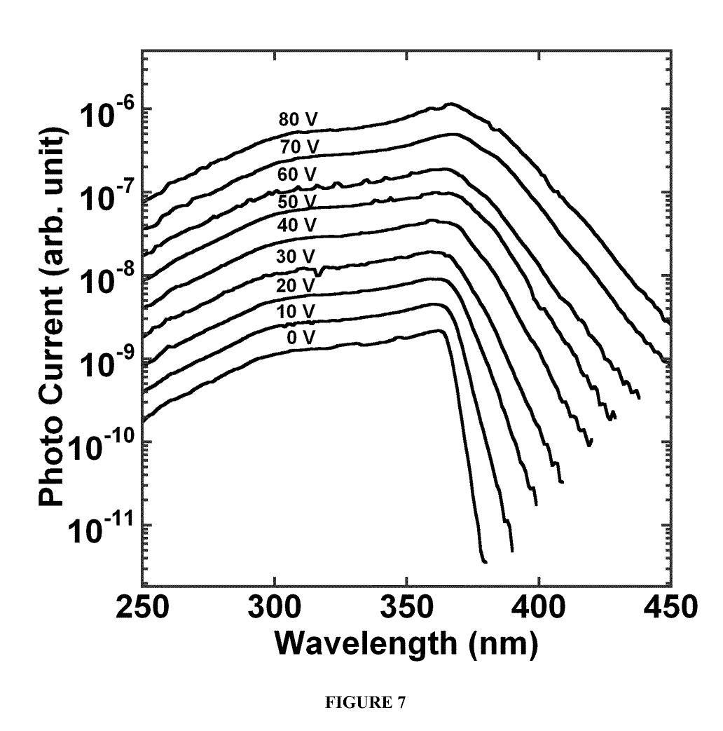

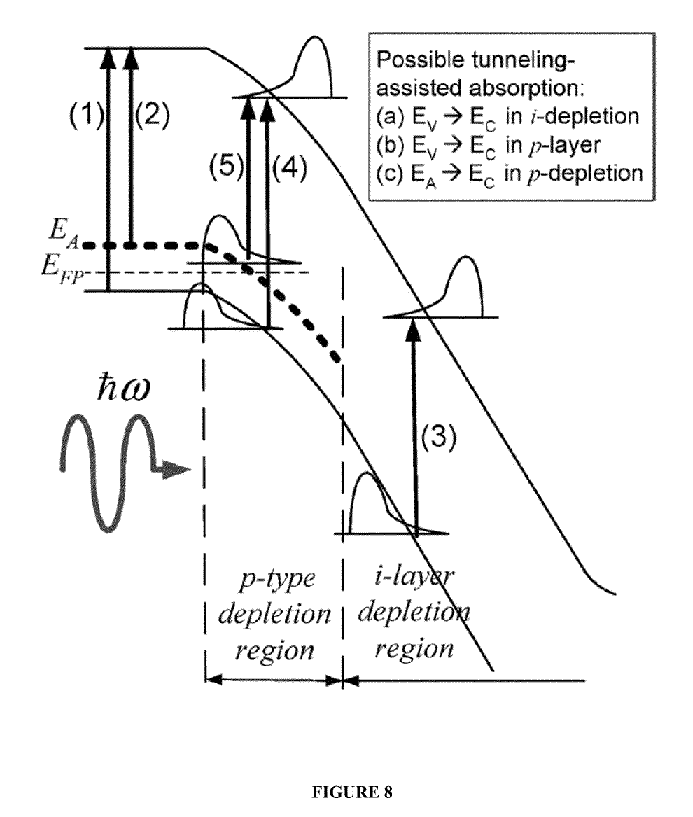

FIG. 7 illustrates the voltage-dependent photocurrent spectral response of a fabricated DUV APD. The device was illuminated from the top at the selected optical wavelength using a UV optical fiber, and the photocurrent was measured with a lock-in amplifier. Bias-dependent responsivity curves were obtained by dividing the measured photocurrent by the incident optical power using a calibrated optical power meter. Note that the short-wavelength (λ<350 nm) spectral responses were almost identical for reverse biases up to about 60 V, and a zero-biased responsivity of about 0.15 A/W was measured at λ=360 nm. However, the curves were split in the plot for clear presentation. The zero-biased photocurrent showed peak absorption at about 364 nm with an absorption edge at about 380 nm. With the increase in reverse bias, the absorption peak shifted slightly to about 370 nm due to the Franz-Keldysh effect. The plot also confirms that the DUV short-wavelength cut-off wavelength for GaN-based APD was well beyond 250 nm. At higher reverse biases, however, the absorption edge significantly extended into the blue band (about 440 nm). The broadened absorption edge and the enhanced red-shifting of the absorption spectrum can be understood schematically in FIG. 8.

Since the UV light was illuminated from the top of the mesa, photons were absorbed through both band-to-band transitions and acceptor-state absorption in the p-type layer [absorption paths (1) and (2) in FIG. 8]. These absorption paths contributed little to the overall photocurrent due to the relatively short diffusion length in GaN. On the other hand, effective photocurrent generation may come from both the tunneling-assisted band-to-band absorption in the depletion region [absorption paths (3) and (4)] and the deep-level acceptor-to-conduction-band absorption in the depleted p-GaN layer [absorption path (5)]. At low reverse biases, most of the depletion region falls in the i-layer, and the photocurrent due to absorption path (5) may be insignificant. As the reverse bias increased, the depletion region extended into the p-type layer due to the relatively low free-hole concentration in the Mg-doped GaN layer. The photocurrent resulting from absorption path (5), therefore, became non-negligible. With the presence of an electric field, the acceptor-state-to-conduction-band absorption also experienced the Franz-Keldysh effect in the depleted p-GaN region. As a result, the measured absorption spectra showed significant red-shifting of the absorption tail at higher reverse bias conditions. This situation was is different from most lower-bandgap PIN diodes where the depletion region can be well-confined in the intrinsic layer and shallow-acceptors are often used in these devices.

To summarize, a high-performance GaN APD technology fabricated on free-standing GaN substrates with reproducible avalanche gains greater than 10 000 at DUV wavelengths (280 nm) have been demonstrated in this example. To the best of the inventors' knowledge, this is the highest linear gain demonstrated by a III-N APD reported to date, showing great performance enhancement and significant yield improvement compared to prior work on GaN APDs grown on sapphire. The spectral responses of the GaN APDs exhibited a unique red-shift in the near-band-edge absorption, possibly due to the deep-level impurity-band absorption in the depletion region. The high avalanche gains were attributed to much-improved fabrication processing and epitaxial growth techniques on free-standing GaN substrates, indicating the possibility of GaN APD arrays manufactured for high-sensitivity DUV applications.

### Example 3

In this example, Al_{0.25}Ga_{0.75}N/GaN heterostructure field-effect transistor (HFET) structures were grown on semi-insulating GaN substrates by MOCVD with a Fe-doped GaN buffer layer. Various surface treatments were employed prior to the epitaxial growth of the structure. The surface treatments, which were intended to remove suspected surface-charge-containing layers on the substrate, included wet chemical etching, in-situ thermal etching, plasma dry etching, and photo-enhanced chemical etching. Photo-enhanced chemical (PEC) etching was effective in achieving microscopically smooth surfaces and in eliminating the surface charge layer on the surface of semi-insulating (SI) GaN substrates. The RMS surface roughness of the PEC-etched surface of the semi-insulating GaN substrate was about 0.1 nm to about 0.2 nm for an about 1×1 μm² scan. Capacitance-voltage measurements showed well-defined 2-dimensional-gas-related charges without any growth-interface-related charges for a HFET grown on a semi-insulating GaN substrate with optimized photo-enhanced chemical etching of the surface.

Experimentally, the HFET structures were grown by MOCVD using a Thomas Swan reactor system equipped with a close-coupled showerhead (CCS) growth chamber having 6×2 inch wafer capacity. Hydrogen (H₂) was used as the carrier gas and was mixed with ammonia (NH₃) as the Group V precursor and with EPIPURE™ (provided by SAFC Hitech, formerly Epichem) trimethylgallium (TMGa) and trimethylaluminum (TMAl) as the Group III precursors. The HFET structures comprised an about 0.4 μm Fe-doped GaN (GaN:Fe) first “buffer” layer, then an about 2 μm unintentionally doped GaN layer (GaN:ud), and finally an about 20 nm Al_{0.25}Ga_{0.75}N cap layer. To characterize the materials and structure, several techniques were used. For example, X-ray diffraction (XRD) was used to evaluate the crystalline quality and to determine the AlGaN cap layer composition. AFM was used to study the microscopic surface morphology before and after the surface treatment step and epitaxial structure growth. Mercury-probe capacitance-voltage (C-V) measurements were used to characterize charges induced by 2-dimensional electron gas (2-DEG) and/or growth interface charges between the substrate and the epitaxial layers. Finally, secondary ion mass spectroscopy (SIMS) was also used.

The GaN substrates were grown by HVPE, where Fe was introduced as a compensating impurity to achieve semi-insulating electrical behavior. After the growth, the substrate surfaces were prepared for epitaxial growth using a CMP process. In order to remove the layer that was suspected to contribute to the interface charge between the substrate and the epitaxial layers, several methods of surface treatments were employed. These included surface layer chemical etching, dry etching by inductively-coupled plasma (ICP), in-situ thermal etching, and photo-enhanced chemical (PEC) etching using the solution described in EXAMPLE 1.

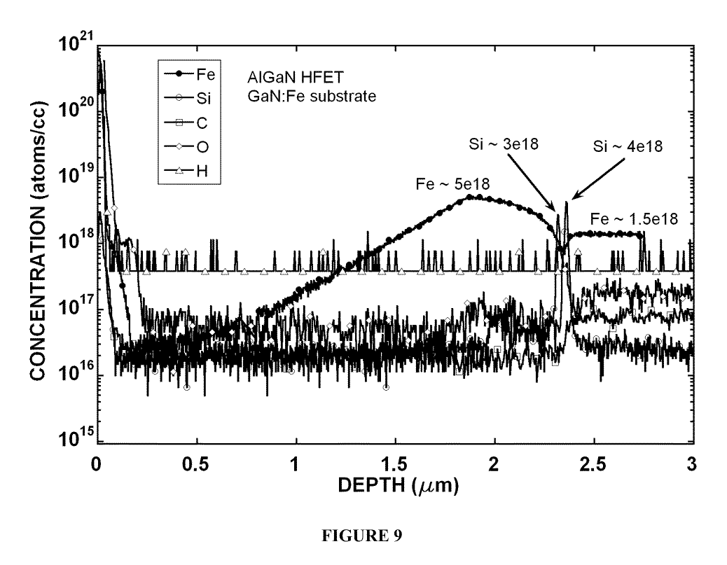

As described, it was believed that the surface layer containing additional charges from impurities such as Si might be introduced during the substrate surface preparation process. A SIMS profile of a HFET grown on a SI—GaN bulk substrate without employing above surface treatments, as shown in FIG. 9, indicates two Si peaks near the interface between the substrate and the GaN substrate. One peak on the epitaxial layer side (having a concentration of about 3×10¹⁸ cm⁻³) was attributed to epitaxial growth and chamber conditions, while the other peak on the substrate side (having a concentration of about 4×10¹⁸ cm⁻³) was attributed to the surface preparation of the GaN substrates. It is noted that other impurities such as C, H, and O were well-controlled throughout the substrate and epitaxial growth, and that Fe doping profile showed delayed turn-on and tailing-off behavior.

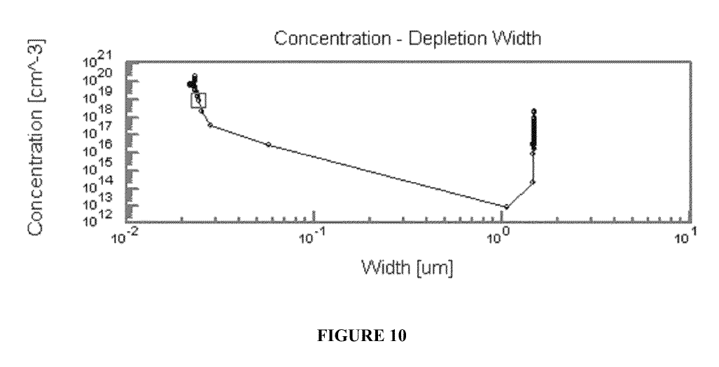

It has been shown that the Si-containing layer on the epitaxial layer side can be compensated by an Fe-doped layer. The Si-containing layer on the substrate side cannot be easily compensated by Fe doping. Delayed turn-on of doping of Fe by ferrocene (Cp₂Fe, bis(cyclopentadienyl)iron) may make the compensation of interface charge layer difficult if the charge is induced by high concentrations of combined Si peaks both from epitaxial growth and substrate surface preparation, as in the case of HFETs on SI—GaN bulk substrates. To provide enough Fe to compensate the charged layer near the growth interface, various pre-purge schemes of Cp₂Fe dopant precursor were investigated. The pre-purge can saturate the reactor with the dopant precursor, and hence could mitigate the delayed turn-on of Fe incorporation. FIG. 10 shows charge vs. depth for HFETs grown with a Cp₂Fe pre-purge, measured by C-V. In this epitaxial structure, the total thickness of the GaN layer was about 1.5 μm. Both a charge layer near the growth interface of about 1.5 μm thickness and a 2-DEG-related charge (having a thickness of about 20 nm) were observed, indicating that a pre-purge of Cp₂Fe may not be able to provide Fe incorporation in an amount sufficient to compensate the surface charged layer.

Removal of the surface charged layer on the SI—GaN substrate may be required prior to the epitaxial growth. For one sample, chemical etching of substrate surface by HCl and deionized water (1:1) at about 100° C. was employed before the growth of HFET. C-V profiles showed a charge near the substrate and epitaxial layer interface.

For another sample, in-situ thermal etching of the surface of SI—GaN substrate was employed in an attempt to remove the charged layer on the surface. The substrate was loaded in the growth chamber after cleaning and then heated up to about 1050° C. prior to the epitaxial growth. A H₂ and NH₃ ambient was used for about 30 min for the in-situ thermal etching of the surface layer. A HFET structure was grown subsequently after the thermal etching of the surface layer without cooling down the substrate. The C-V profile again shows charges near the substrate and epitaxial layer interface, and this may be due to the incomplete removal of Si on the surface layer.

ICP etching was employed on a different sample to remove the surface layer by dry etching. ICP etching resulted in macroscopically (as viewed under a Nomarski optical microscope) decent but microscopically (as viewed using an AFM) rough surface under the etching conditions employed. RMS surface roughness as measured by AFM increased to about 4 to about 6 nm (for 1×1 μm² scan) from sub-nm level by ICP etching. A HFET structure grown on an ICP-etched surface of the substrate exhibited an interface charge near the substrate and epitaxial layer interface, which may be related to the rough surface of the substrate.

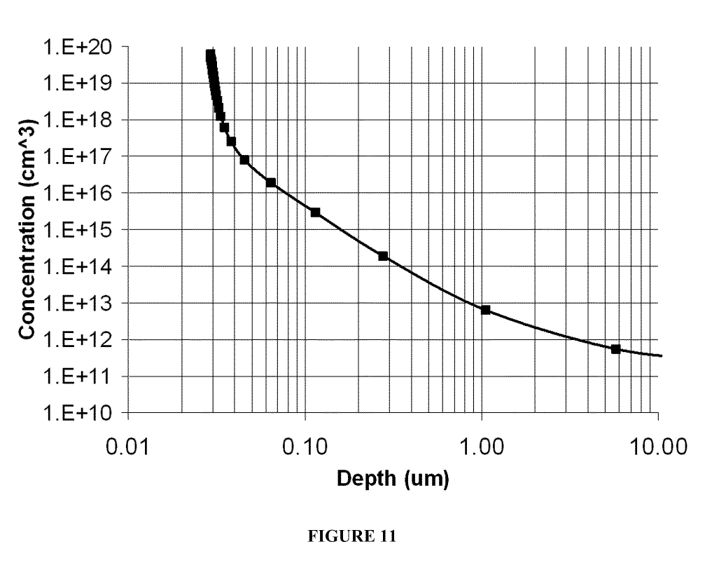

Finally, PEC etching was employed. A UV lamp was used as a light source for the PEC etching, and KOH and K₂S₂O₈ diluted in the deionized water were used as an etchant. By using the better etching conditions from EXAMPLE 1, a smooth surface both macroscopically and microscopically was achieved. RMS surface roughness before and after PEC etching was maintained in the order of sub-nm (about 0.1 to about 0.2 nm depending on substrates for 1×1 μm² scan area after PEC etching). The HFET structure was grown on the PEC-etched surface of SI—GaN substrate. No interface charge was observed near the epitaxial growth interface for PEC etched surface, as shown in FIG. 11. For comparison, a SI—GaN substrate without PEC etching treatment before the growth was loaded in the same HFET growth run. A charge concentration peak near about 2 μm in depth was observed, indicating that the interface-related charge still existed for the non-treated surface.

To summarize this example, various surface treatment methods were used to remove the surface charge-containing layer on SI—GaN substrates. The charge was not effectively removed by chemical etching, in-situ thermal etching, and ICP dry etching. Some of these techniques induced degradation of the surface during the treatment. PEC etching of SI—GaN substrates resulted in a very smooth surface and the elimination of surface charge for HFETs grown on PEC-etched SI—GaN substrates.

### Example 4

In this example, GaN/InGaN double-heterojunction bipolar transistors (DHBTs) were grown on sapphire substrates using direct-growth techniques. The surface leakage current properties of such devices were studied. As will be described below, surface leakage current densities of about 9.6×10⁻⁵ to about 5.8×10⁻⁴ A/cm were obtained for current collector densities (J_{C}) of about 0.5 to about 50 A/cm² on DHBTs having no surface passivation. Through optimized epitaxial growth, and the use of the surface treatment technique disclosed herein, a DHBT with a common-emitter D.C. current gain (β) of about 42, a differential current gain (β_{AC}) of about 54, a J_{C} of about 5.2 kA/cm², and an open-base common-emitter breakdown voltage (BV_{CEO}) of about 75 V was obtained. To the best of the inventors' knowledge, such a device exhibits the highest D.C. current gain for direct-growth npn GaN/InGaN DHBTs to date.

The graded-emitter GaN/InGaN DHBT structures produced in this example were grown on c-plane sapphire substrates in a Thomas-Swam MOCVD system. High-quality GaN/InGaN DHBT structures were achieved with reduced bulk-defects and “V”-defect densities on sapphire substrates. The epitaxial layers comprised an about 2500 nm unintentionally doped GaN buffer layer, an about 1000 nm GaN sub-collector layer (Si-doped, with a free electron concentration (n) of about 3.7×10¹⁸ cm⁻³), an about 500 nm n-GaN collector layer (Si-doped, n=about 1.0×10¹⁷ cm⁻³), an about 30 nm InₓGa₁₋ₓN (x=about 0 to about 0.03) collector grading layer, an about 100 nm Mg-doped In_{0.03}Ga_{0.97}N base layer (Mg-doped, with a free-hole concentration (p) of about 2×10¹⁸ cm⁻³, Rₛ=about 27.2 kΩ/cm³), an about 30 nm InₓGa₁₋ₓN (x=about 0.03 to about 0) emitter-grading layer, and an about 70 nm n-GaN emitter cap layer (n=about 1×10¹⁹ cm⁻³). The collector grading layer was used to mitigate the bandgap discontinuity in the base-collector junction, and the emitter-grading layer was used to accommodate the strain induced at the base-emitter (BE) junction.

The device fabrication employed a two-step chlorine-based mesa etching processing using an inductively coupled plasma etching system. The first mesa etching step was used to expose the base layer and the second etching step stopped at the n-type sub-collector. After the mesa etching, the wafer piece was surface treated in a dilute KOH/K₂S₂O₈ solution under ultraviolet illumination to remove the dry-etching induced surface damage. Ni/Ag/Pt films were deposited as the base contact, and Ti/Al/Ti/Au films were used for the collector and emitter contact.

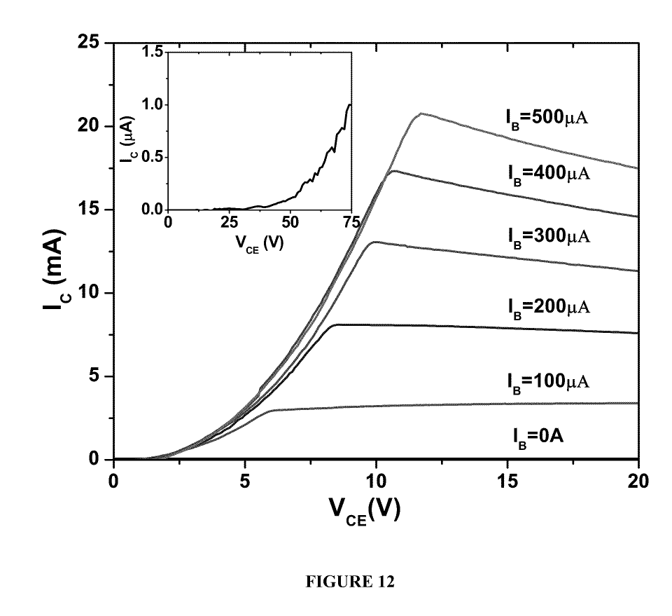

The HBTs were evaluated in a Keithley 4200 semiconductor characterization system. The fabricated devices in this example did not have any surface passivation to explore the as-etched device performance. FIG. 12 shows the measured common-emitter characteristics of a GaN/InGaN DHBT with an emitter area (A_{E}) of about 20×about 20 μm². At I_{B}=about 500 μA, the measured I_{C} was about 21 mA at V_{CE}=about 11 V, which corresponded to J_{C}=about 5.2 kA/cm² and β=about 42. The self-heating effect was observed for I_{C} greater than about 10 mA due to the low thermal conductivity of the sapphire substrate. BV_{CEO}=about 75 V was determined at I_{C}=about 1 μA with I_{B}=0 (shown in the insert of FIG. 12) and the BV_{CBO} was about 78 V. The nonlinear turn-on characteristics in the device's saturation region may be due to the current blocking at the base-collector heterojunction.

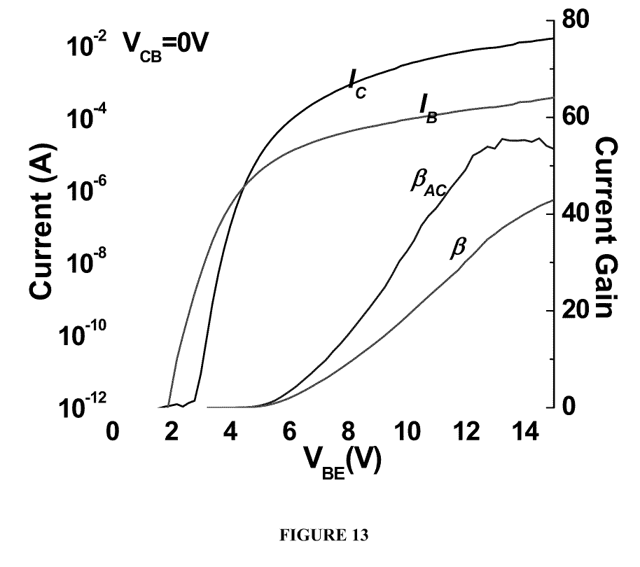

A measured Gummel plot with V_{CB}=0 is shown in FIG. 13. The I_{C}-I_{B} crossover point was about 1.1 μA. Beyond this point, both β(=I_{C}/I_{B}) and β_{AC} (=dI_{c}/dI_{B}) increased monotonically and reached maximum values of about 42 and about 54, respectively. The series resistance effect was significant even in low current regions. The high resistance in the extrinsic base region of a mesa-type HBT resulted from the relatively low free-hole concentration in typical GaN-based npn transistors. As the device size increased, the maximum β's dropped from about 42 for devices with A_{E}=about 400 μm² to about 25 for those with A_{E}=about 10,000-μm².

The fact of βbeing lower than β_{AC} may be due to trap states at the BE junction. It is known that surface states have long capture/emission times in III-N materials. In the Gummel measurement, these states contributed a current sink for I_{B} but may not have responded as quickly at the rate of V_{BE} sweep. As slow states did not respond effectively to the small-signal fluctuation, the small increment in the I_{B} was expended to sustain the emitter carrier injection, to a larger extent, other than the trap-related recombination. As a result, it was common to observe a higher β_{AC} than β in III-N HBTs. The reduced current gain in larger area devices was, on the other hand, associated with defects in the bulk region. As more growth-related defects were included in larger-area devices, the space-charge recombination was enhanced. The base transport factor and the emitter injection efficiency was reduced. As a result, lower β values were observed in larger-area HBTs.

To assess the impact of surface states in an HBT, a commonly accepted surface leakage current assessment methodology in conventional III-V HBTs was used. A set of normalized current density (J_{C}/β≡I_{B}/A_{E}) of a fixed J_{C} were plotted against the emitter's perimeter-to-area ratios (L_{E}/A_{E}). The surface leakage current component was then calculated from the slope of each curve for fixed J_{C}'s.

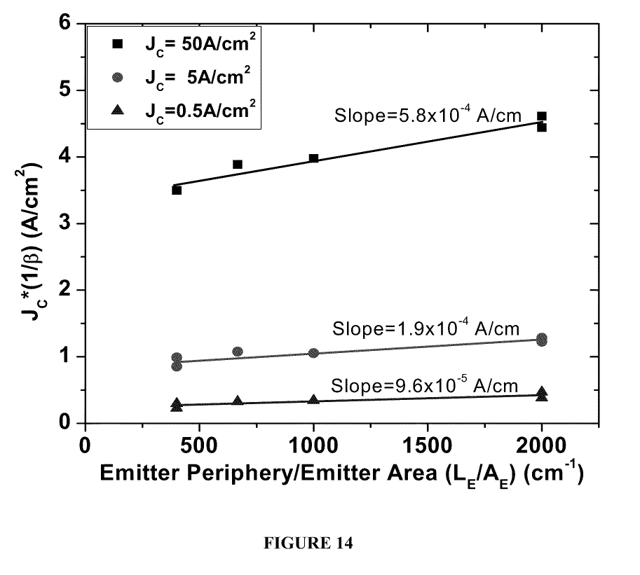

As shown in FIG. 14, four DHBTs with square-shaped emitters (A_{E} of about 400, about 1,600, about 3,600, and about 10,000 μm²) were evaluated at J_{C}=about 0.5, about 5, and about 50 A/cm², respectively. J_{C}=about 0.5 A/cm² was chosen at the proximity of the I_{C}-I_{B} crossover point to evaluate the contribution of the surface leakage in I_{B} at β of about 1. The surface leakage current density (K_{B,surf}) was calculated from the linearly-fitted slope for each curve.

The data showed that K_{B,surf} increased slightly from about 9.6×10⁻⁵ A/cm to about 5.8×10⁻⁴ A/cm as J_{C} increased from about 0.5 A/cm² to about 50 A/cm². However, the percentage of the surface leakage current in the base current, (K_{B,surf}L_{E})/I_{B}, decreased from about 49% at J_{C}=about 0.5 A/cm² to about 26% at J_{C}=about 50 A/cm² for devices with A_{E}=about 400 μm². For devices with A_{E}=about 10000 μm², the surface leakage current contributed to about 17% of the I_{B} at J_{C}=about 0.5 A/cm², and that decreased to about 6.6% at J_{C}=about 50 A/cm².

The reduced influence of the surface leakage on I_{B} for devices with smaller L_{E}/A_{E} ratios was a result of the well-known emitter size effect in HBT. It should, however, be noted that the emitter crowding effect could be significant due to high base resistance in npn GaN/InGaN DHBTs. The actual surface leakage current may be overestimated in K_{B,surf}. The results showed that the surface leakage was not a limiting factor for achieving high β in the fabricated devices, but may have played a significant role in current gain dispersion. To further enhance the device performance, a proper surface passivation may be required. Nevertheless, the results clearly demonstrate that high current drive npn GaN/InGaN DHBTs were fabricated using a conventional direct-growth approach without incurring a complicated base re-growth technique.

In summary, this example demonstrates that high-current-gain npn GaN/InGaN DHBTs on a sapphire substrate can be achieved using the surface treatment method disclosed herein to significantly reduce the surface leakage current. A state-of-the-art GaN/InGaN DHBT with β greater than about 42, β_{AC} greater than about 54, J_{C} greater than about 5.2 kA/cm², and BV_{CEO} greater than about 75 V was fabricated. The fabricated devices demonstrated the feasibility of realizing high-performance GaN/InGaN DHBTs using a simple direct-growth approach and the wet KOH/K₂S₂O₈ electrode-less surface treatment technique.

To summarize and reiterate, in contrast to existing III-N etching techniques, the methods and devices disclosed herein advantageously make use of a low-concentration electrode-less wet surface-treating technique to maintain crystallographic stoichiometry on already-etched III-N surfaces. The methods can also effectively remove etching damage caused by conventional III-N plasma-enhanced dry etching steps. As a result, the methods produce devices that can suppress leakage currents arising from side-wall etching damage. In one embodiment described in the EXAMPLES, a potassium hydroxide and potassium persulfate mixture effectively suppressed at least one order of magnitude of leakage current in GaN PIN diodes grown on SiC substrates, when compared to controlled devices fabricated without the surface treatment. GaN avalanche photodiodes were also fabricated, using the surface treatment technique developed in this invention, to achieve among the highest avalanche gains reported to date. The methods and devices described herein provide a simple and effective way to suppress side-wall leakage currents in III-N semiconductor devices with already-etched mesas.

The various embodiments of the present invention are not limited to the particular formulations, process steps, and materials disclosed herein as such formulations, process steps, and materials can vary somewhat. Moreover, the terminology employed herein is used for the purpose of describing exemplary embodiments only and the terminology is not intended to be limiting since the scope of the various embodiments of the present invention will be limited only by the appended claims and equivalents thereof. For example, temperature and time parameters can vary depending on the particular materials used.

Therefore, while embodiments of this disclosure have been described in detail with particular reference to exemplary embodiments, those skilled in the art will understand that variations and modifications can be effected within the scope of the disclosure as defined in the appended claims. Accordingly, the scope of the various embodiments of the present invention should not be limited to the above discussed embodiments, and should only be defined by the following claims and all equivalents.

What is claimed is:

1. A method of treating a surface of a semiconductor device, the method comprising:
contacting an etched surface of a component of a semiconductor device with a solution comprising a metal hydroxide and an oxidizing agent; and
reducing a roughness of the etched surface;
wherein the etched surface is formed from a composition comprising a nitride of a group III element.

2. The method of claim 1, wherein the metal hydroxide is potassium hydroxide.

3. The method of claim 2, wherein the potassium hydroxide has a concentration less than or equal to about 0.01 M.

4. The method of claim 1, wherein the oxidizing agent is potassium persulfate.

5. The method of claim 4, wherein the potassium persulfate has a concentration less than or equal to about 0.01 M.

6. The method of claim 1, further comprising illuminating the etched surface with a light source configured to produce ultraviolet light.

7. The method of claim 6, wherein the ultraviolet light has a wavelength of about 180 nanometers to about 380 nanometers.

8. The method of claim 6, wherein the ultraviolet light has a power less than or equal to about 0.5 Watts per square centimeter.

9. The method of claim 1, wherein the contacting occurs at a temperature of less than or equal to about 100 degrees Celsius.

10. The method of claim 1, wherein the contacting occurs for a duration of less than or equal to one hour.

11. The method of claim 1, wherein the semiconducting device has a leakage current that is reduced at least one order of magnitude after the reducing.

12. The method of claim 1, wherein the reducing the roughness of the etched surface comprises removing etching damage.

13. A method of fabricating a semiconductor device, the method comprising:
etching a surface of a component of a semiconductor device, wherein the surface is formed from a composition comprising a nitride of a group III element;
contacting an etched surface of the component of the semiconductor device with a solution comprising potassium hydroxide at a concentration less than or equal to about 0.01 M and potassium persulfate at a concentration less than or equal to about 0.01 M, wherein the contacting comprises a temperature less than or equal to about 100 degrees Celsius and a duration less than or equal to about one hour; and
reducing a roughness of the etched surface.

14. The method of claim 13, wherein the reducing the roughness of the etched surface comprises removing damage from the etched surface caused by the etching.

15. The method of claim 13, wherein the semiconducting device has a leakage current that is reduced at least one order of magnitude after the contacting.

16. An avalanche photodiode device, comprising:
a p-type layer of a nitride of a group III element;
an n-type layer of the nitride of the group III element; and
an intrinsic or unintentionally doped layer of the nitride of the group III element disposed between the p-type and n-type layers;
wherein the avalanche photodiode device exhibits a photocurrent gain greater than or equal to about 10⁴ and a dark current less than or equal to about 10⁻⁷ Amps per square centimeter at a bias value less than or equal to about 50% of an avalanche breakdown voltage for the avalanche photodiode device.

17. The avalanche photodiode device of claim 16, wherein the nitride of the group III element is gallium nitride.

18. The avalanche photodiode device of claim 16, further comprising an etched mesa structure comprising an etched surface, wherein the etched surface was contacted with a solution comprising potassium hydroxide at a concentration less than or equal to about 0.01 M and potassium persulfate at a concentration less than or equal to about 0.01 M.

19. The avalanche photodiode device of claim 18, wherein the avalanche photodiode device has a leakage current that is reduced at least one order of magnitude than if the etched surface was not contacted with the solution.

20. The avalanche photodiode device of claim 16, wherein the avalanche photodiode is sensitive to ultraviolet radiation having a wavelength of about 280 nanometers to about 360 nanometers.

21. A double heterojunction bipolar transistor, comprising:
a first layer comprising a first composition comprising a nitride of a group III element, wherein the first layer is p-type or n-type;
two layers, each comprising a second composition comprising a nitride of a group III element, wherein the two layers have an opposite polarity from the first layer, and wherein the first layer is disposed between the two layers; and
an etched mesa structure having an etched surface, wherein the etched surface was contacted with a solution comprising potassium hydroxide at a concentration less than or equal to about 0.01 M and potassium persulfate at a concentration less than or equal to about 0.01 M;
wherein the double heterojunction bipolar transistor exhibits a common emitter current gain greater than 1.
